(19) United States
(12) Patent Application Publication
(10) Pub. No.: US 2019/0272983 A1
(43) Pub. Date: Sep. 5, 2019

(54) SUBSTRATE HALO ARRANGEMENT FOR IMPROVED PROCESS UNIFORMITY

(71) Applicant: Varian Semiconductor Equipment Associates, Inc., Gloucester, MA (US)

(72) Inventors: Jay Wallace, Danvers, MA (US); Simon Ruffell, South Hamilton, MA (US); Kevin Anglin, Somerville, MA (US); Tyler Rockwell, Wakefield, MA (US); Chris Campbell, Newburyport, MA (US); Kevin M. Daniels, Lynnfield, MA (US); Richard J. Hertel, Boxford, MA (US)

(73) Assignee: Varian Semiconductor Equipment Associates, Inc., Gloucester, MA (US)

(21) Appl. No.: 15/969,254

(22) Filed: May 2, 2018

Related U.S. Application Data
(60) Provisional application No. 62/637,164, filed on Mar. 1, 2018.

(51) Int. Cl. H01J 37/32; H01L 21/67; H01L 21/687

(52) U.S. Cl. CPC H01J 37/32724; H01L 21/67069; H01J 2237/3323; H01J 2237/3341; H01J 2237/3321; H01L 21/68735

(57) ABSTRACT

A substrate assembly may include an outer halo, the outer halo comprising a first material and defining a first aperture. The substrate assembly may also include a halo ring, comprising a second material and disposed at least partially within the first aperture. The halo ring may define a second aperture, concentrically positioned within the first aperture, wherein the halo ring is coupled to accommodate a substrate therein.

### RELATED APPLICATIONS

This application claims priority to U.S. Provisional Patent application No. 62/637,164, filed Mar. 1, 2018, entitled SUBSTRATE HALO ARRANGEMENT FOR IMPROVED PROCESS UNIFORMITY, and incorporated by reference herein in its entirety.

### FIELD

Embodiments of the present disclosure relate to semiconductor workpiece processing and, more particularly, to semiconductor workpiece processing using a substrate halo for process uniformity

### BACKGROUND

For plasma-aided and ion beam-aided device processing, a goal is often to generate process uniformity across a substrate. Substrates, such as semiconductor wafers, are often positioned to be surrounded by hardware, such as halos, to protect a process chamber, substrate, or other components not designed to receive a plasma or ion beam treatment. While a large portion of a substrate may receive relatively uniform treatment, a frequent observation is the presence of edge effects near the periphery of a substrate, where the edge effects may include non-uniform process results, as well as contamination, particle generation, and other unwanted results.

With respect to these and other considerations the present disclosure is provided.

### BRIEF SUMMARY

In one embodiment, a substrate assembly may include an outer halo, the outer halo comprising a first material, and defining a first aperture. The substrate holder may include a halo ring, where the halo ring includes a second material and is disposed at least partially within the first aperture. The halo ring may define a second aperture, concentrically positioned within the first aperture, wherein the halo ring is coupled to accommodate a substrate therein.

In another embodiment, a substrate holder assembly may include a substrate platen, where the substrate platen is disposed to support a substrate at a substrate position. The substrate holder assembly may also include a halo ring, the halo ring being disposed around the substrate position. The substrate holder assembly may further include an outer halo, where the outer halo comprises a first material, and is disposed around the halo ring. The outer halo may define a first aperture, wherein the outer halo is disposed to engage the halo ring. The halo ring may comprise a second material and may be disposed at least partially within the first aperture. The halo ring may define a second aperture, concentrically positioned within the first aperture.

In another embodiment, a processing apparatus may include a process chamber, and a substrate holder assembly, disposed in the process chamber. The substrate holder assembly may include a substrate platen, where the substrate platen is disposed to support a substrate at a substrate position. The substrate holder assembly may also include a halo ring, the halo ring being disposed around the substrate position. The substrate holder assembly may further include an outer halo, comprising a first material, where the outer halo is disposed around the halo ring, and configured to engage the halo ring. The halo ring may comprise a second material, different from the outer halo.

### BRIEF DESCRIPTION OF THE DRAWINGS

The accompanying drawings illustrate example approaches of the disclosure, including the practical application of the principles thereof, as follows:

FIG. 1A is a schematic view illustrating a side view of a processing apparatus in accordance with embodiments of the present disclosure;

FIG. 1B is a schematic view illustrating face view of a substrate holder assembly in accordance with embodiments of the present disclosure;

FIG. 1C is a schematic view illustrating a side view of another processing apparatus in accordance with embodiments of the present disclosure;

FIG. 2A is a front perspective view of another substrate holder assembly in accordance with embodiments of the present disclosure;

FIG. 2B is a sectional view along the cut A-A of FIG. 2A;

FIG. 2C is an enlarged view of a portion of FIG. 2B; and

FIG. 3 is a perspective view of an additional substrate holder assembly in accordance with other embodiments of the present disclosure.

The drawings are not necessarily to scale. The drawings are merely representations, not intended to portray specific parameters of the disclosure. The drawings are intended to depict example embodiments of the disclosure, and therefore are not be considered as limiting in scope. In the drawings, like numbering represents like elements.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

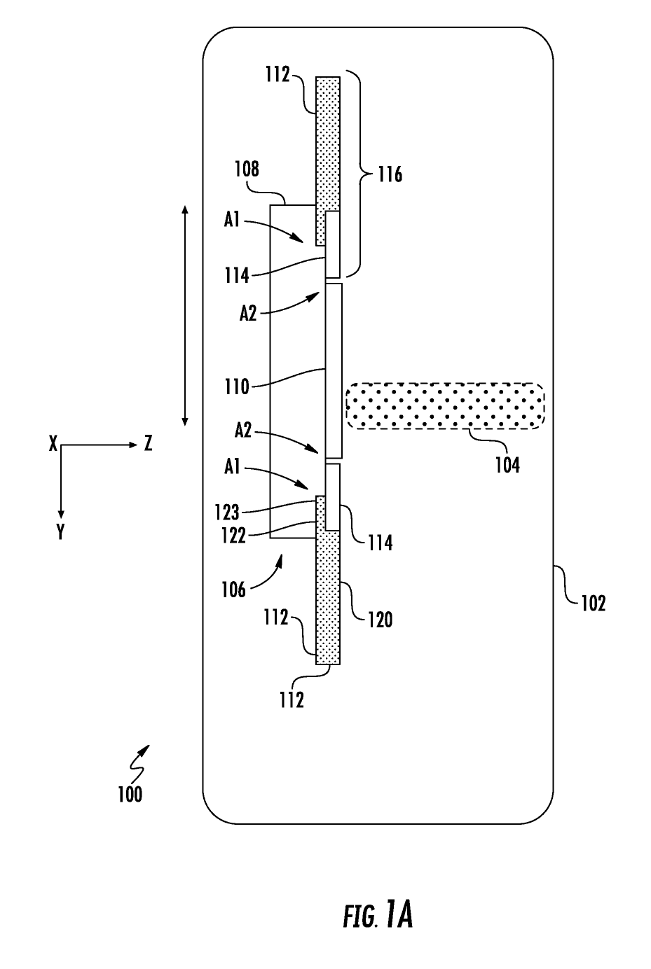

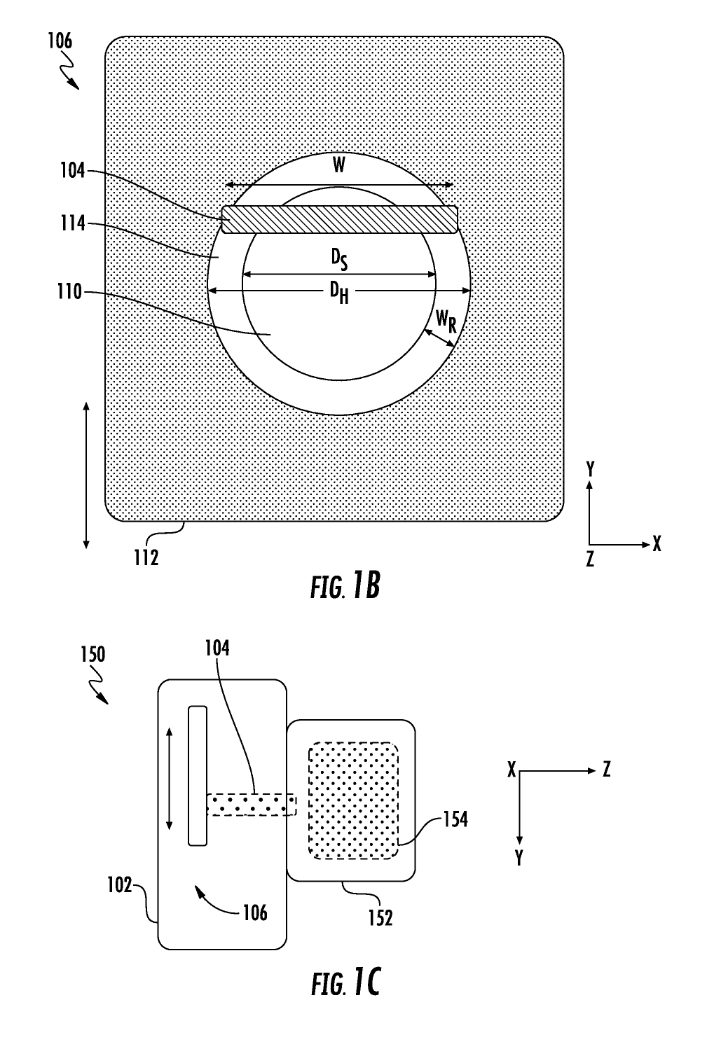

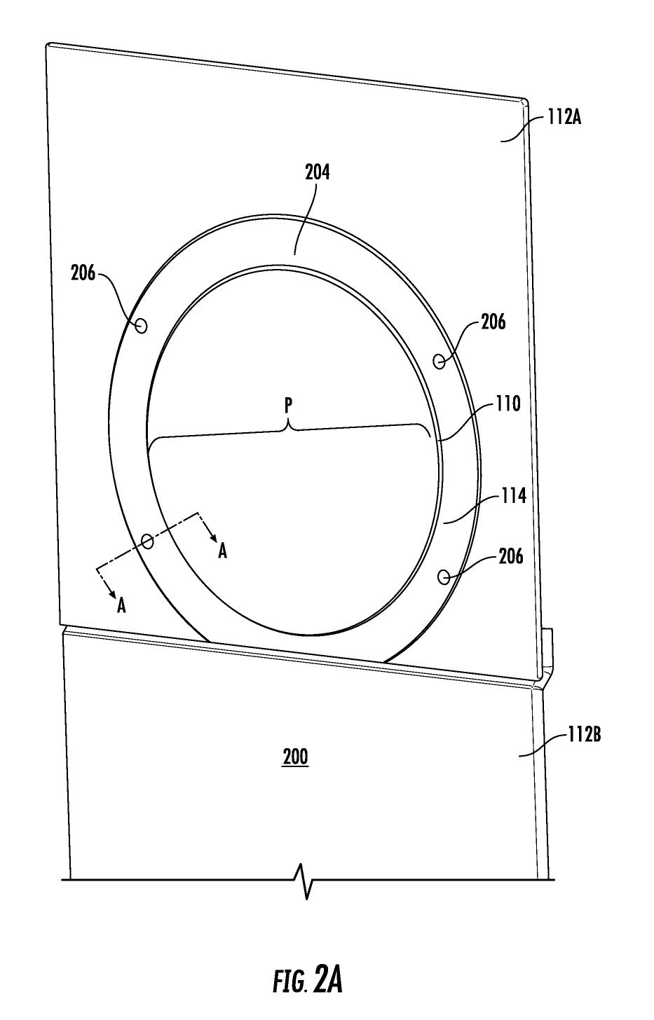

Referring now to FIG. 1A, a processing apparatus 100 is shown, where the processing apparatus 100 may be used for processing substrates such as semiconductor wafers. The processing apparatus 100 includes a process chamber 102. The process chamber 102 includes a substrate holder assembly 106, where the structure and function of the substrate holder assembly 106 is detailed below. In brief, the substrate holder assembly 106 may include a substrate platen 108, disposed to hold a substrate 110, an outer halo 112, and a halo ring 114. The outer halo 112 and halo ring 114 may function as a substrate assembly 116, to adjust and improve processing of substrates. As shown in FIG. 1A, the process chamber 102 may include processing species 104, used to process a substrate 110, disposed in the substrate assembly 116.

As further shown in FIG. 1A, the outer halo 112 defines a first aperture, whose edges are shown by A1, while the halo ring 114 defines a second aperture, whose edges are shown by A2, where the second aperture is concentrically positioned within the first aperture. As shown, the halo ring 114 may be coupled to accommodate a substrate 110 within the second aperture.

The processing apparatus 100 according to different embodiments may be an etching tool, to perform etching operations on the substrate 110, a deposition tool, or a combination of etching and deposition tool. In some embodiments, the processing apparatus 100 may be an implanting tool to introduce implanted species into the substrate 110. As such, the processing apparatus 100 may be a plasma-based tool, including a plasma etching tool such as a reactive ion etching tool, a plasma doping (PLAD) apparatus, a plasma assisted chemical vapor deposition (PECVD) tool, an ion beam tool, a reactive ion beam etching tool, or other tool.

As shown schematically in FIG. 1A, the processing apparatus 100 may generate and contain processing species 104, where the processing species 104 may represent the appropriate species to perform substrate processing of substrate 110. Thus, the processing species may include ions, reactive ions, reactive neutrals, implanting species, and so forth. While the processing species 104 are shown as contained within the process chamber 102, in various embodiments, the processing apparatus 100 may include a plurality of chambers, including ion sources, plasma sources, separate from the process chamber 102. In other embodiments, the process chamber 102 may be a plasma chamber. The embodiments are not limited in this context.

Turning now to FIG. 1B there is shown a face view, illustrating one embodiment of the substrate assembly 116. In this example, the processing species 104 are configured as an elongated ion beam or ribbon beam, shown in cross-section within the X-Y plane. The ribbon beam may be provided from a plasma chamber through an extraction plate as in known apparatus. Referring now to FIG. 1C, a processing apparatus 150 is shown, where the processing apparatus 150 includes a plasma chamber 152, adjacent the process chamber 102. The processing species 104 are extracted as a ribbon beam from a plasma 154 in the plasma chamber 102 as in known apparatus.

As indicated in FIGS. 1B and 1C, the substrate holder assembly 106 may be scanned in some embodiments, along a direction parallel to the Y-axis, as shown by the arrows. In some embodiments the ribbon beam containing the processing species 104 may be characterized by a width W, where the width W exceeds the substrate diameter Ds. In this manner, the entirety of the substrate 110 may be treated with the processing species 104.

According to various embodiments, the outer halo 112 may be composed of a first material, such as any suitable material. The outer halo may be, for example, a metal coated with a ceramic or other material, where the outer halo is designed to provide resistance to treatment by the ion beam of processing species 104. According to some embodiments, the halo ring 114 may comprise a second material, where the second material may differ from the first material.

In particular embodiments, the halo ring 114 may be coupled to the outer halo 112 in a reversibly detachable manner, as detailed below. The halo ring 114 may accordingly represent any number of different halo rings, where the material of the halo ring 114 may be selected according to a particular application. Thus one halo ring 114 may be substituted for another halo ring, allowing for replacement due to wear or damage. Additionally, a first halo ring made of a first halo ring material may be substituted for a second halo ring made of a second halo ring material, when appropriate. For example, when the material of substrate 110 is changed or when the processing conditions of the processing apparatus 100 are sufficiently altered, a swap of halo ring 114 for another halo ring may be appropriate.

One function of the substrate assembly 116 according to various embodiments of the disclosure is to extend the diameter of the substrate 110, in the sense where the halo ring 114 may mimic certain properties of the substrate 110. As an example, when the substrate 110 is a silicon wafer or silicon alloy wafer, the halo ring 114 may be composed of a similar material, such as silicon or silicon carbide. In this manner, edge effects that may otherwise be generated near the edges of the substrate 110 by the process species 104 may be reduced or eliminated, because the substrate 110 and halo ring 114 “appear” appear to the processing species 104 as a substrate having the diameter Du. Thus, because the width W may exceed the diameter of the substrate Ds, any edge effects may occur at the outer edges of the ribbon beam defined by the processing species 104 or the outer edge of the halo ring 114.

By way of reference, in known halo arrangements, the halo may be a monolithic piece, formed of a metal, such as titanium to provide mechanical and thermal robustness under treatment by an ion beam or plasma. As such, edge effects near the region where the substrate meets the halo may be generated, at least in part due to the differences in material between substrate and halo.

In accordance with some non-limiting embodiments, the diameter D_{H} may exceed the width W, wherein during scanning, the outer edges of the ribbon beam defined by the process species 104 are scanned over material of the halo ring 114, at the widest part. According to various embodiments, the diameter D_{H} may exceed 300 mm, and in some cases, may be in the range of 450 mm. A width W_{R} of the halo ring 114 may in the order of 15 mm to 75 mm. The embodiments are not limited in this context.

According to different embodiments, the halo ring 114 may be mechanically coupled to the outer halo 112 in different manners. As shown in FIG. 1A, the outer halo 112 may comprise an outer portion 120 and a ledge 122, wherein the outer portion 120 comprises a first thickness and the ledge 122 comprises a second thickness, less than the first thickness, wherein an inner edge of the ledge 122 defines the first aperture, and wherein the ledge 122 is disposed to engage the halo ring 114. Notably, the halo ring 114 may be thinner than the outer portion 120, so the outer halo 112 and the halo ring 114, disposed on the ledge 122, may be coplanar with one another. An inner edge 123 of the ledge 122 defines the first aperture, and wherein the ledge is disposed to engage the halo ring.

In various embodiments, a substrate assembly may further include a fastener assembly, where the fastener assembly is disposed to reversibly attach the outer halo 112 to the halo ring. 114.

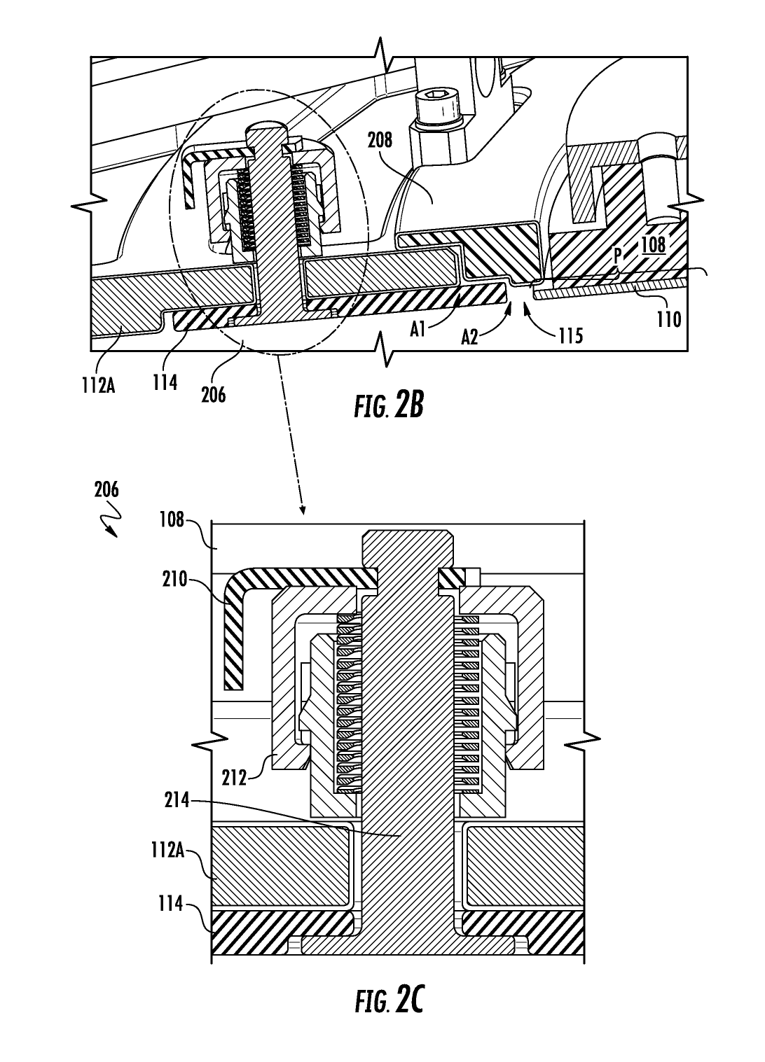

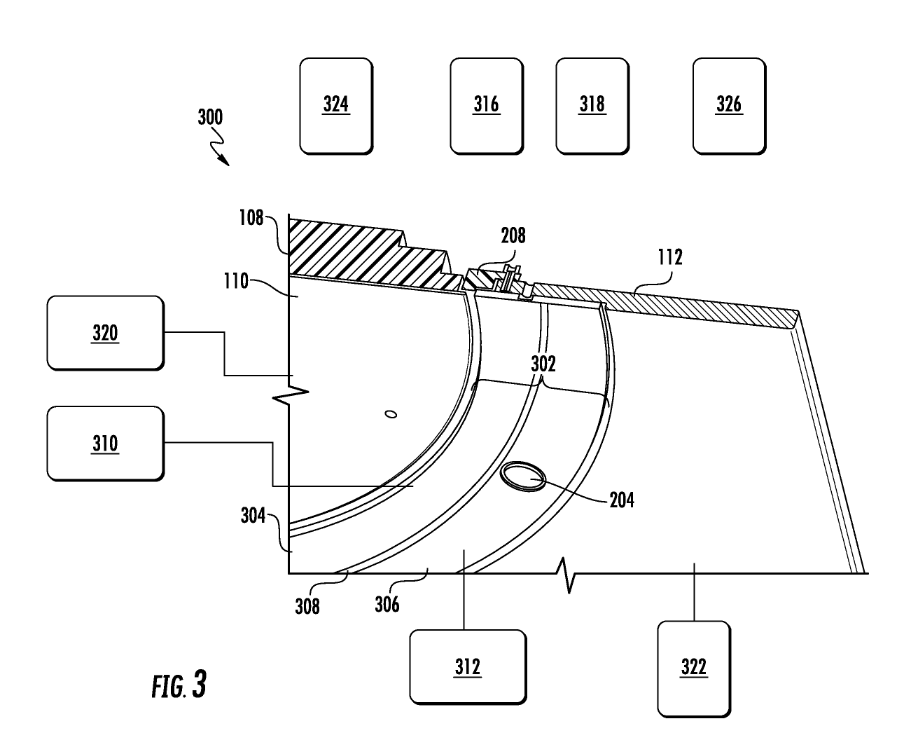

FIG. 2A depicts a substrate assembly 200, according to further embodiments of the disclosure. The substrate assembly 200 is arranged as an upper halo 112A and a lower halo 112B, where a halo ring 114 is arranged concentrically within the upper halo 112A. The substrate assembly 200 further includes a fastener assembly, arranged as a plurality of fasteners 206, coupling the halo ring 114 to the upper halo 112A. The halo ring 114 may also engage hidden pins 204, distributed around the circumference.

Turning now to FIG. 2B, there is shown a cross-sectional view through the section A-A of FIG. 2A, near a fastener 206. As shown therein, the substrate assembly 200 may also include a backside gap ring 208 to prevent electric fields or material from penetrating in the region between substrate 110 and halo ring 114. The backside gap ring 208 is positioned behind a portion of the halo ring 114 and also within a gap 115 between the halo ring 114 and the substrate position P for substrate 110, blocking material from entering this gap when the substrate 110 is in place. The provision of a backside gap ring 208 may allow for alternative shapes, coatings, materials, and bias to be used in conjunction with a substrate holder assembly.

In this embodiment, the fastener 206 includes a stud 214, where the stud 214 may be a ceramic or a coated material. As shown in the enlarged view of FIG. 2C, the fastener 206 may further include a clip 210, and self-contained spring capsule assembly 212. The self-contained spring capsule assembly 212 may be configured to limit the force generated to clamp the halo ring 114 to the outer halo 112. In exemplary embodiments, the maximum force generated by the fastener 206 may be 1 lb. to 1.5 lbs. This limitation of clamping force aids in ensuring the halo ring 114 does not break, especially useful in embodiments where the halo ring 114 is made of a brittle material, such as silicon. In other embodiments, a spring clip may be used in lieu of the self-contained capsule assembly. The embodiments are not limited in this context.

Turning to FIG. 3 there is shown an embodiment of a substrate assembly 300, where a halo ring 302 comprises an outer ring 306 and an inner ring 304, disposed within the outer ring 306. The inner ring 304 may define the second aperture as described above. The outer ring 306 and inner ring 304 may be separated from one another or electrically isolated from one another by a gap or spacer, shown as a spacer 308 in the example of FIG. 3. In some embodiments, the outer ring 306 comprises a first ring material, and the inner ring 304 comprises a second ring material, different from the first ring material. According to some embodiments, the inner ring 304 may be electrically biased, or the outer ring 306 may be electrically biased, while in some embodiments the inner ring 304 and outer ring 306 may be individually coupled to receive different electrical bias, as shown by the voltage source 310, and voltage source 312, respectively. In some embodiments, the substrate platen 108 may also be coupled to a voltage source 320, while the outer halo 112 is separately coupled to a voltage source 322. Accordingly, during operation, voltages applied to the inner ring 304 and outer ring 306 may be the same, or may differ from one another. Additionally, one or both of the inner ring 304 and the outer ring 306 may be biased at a same voltage as a voltage applied to the substrate platen 108, or a different voltage from the voltage applied to substrate platen 108. Similarly, the outer halo 112 may be coupled to receive the same or different voltage from the voltage applied to any of the inner ring 304, outer ring 306, and substrate platen 108.

In one embodiment, the inner ring 304, outer ring 306, or the two, may be configured to receive heating, separately from any heating provided to the substrate 110, as shown by the heater 316 and heater 318, respectively. According to different embodiments, the outer ring 306 and inner ring 304 may be coupled to receive different temperatures from one another. The substrate platen 108 or substrate 110 may be coupled to a heater 324 to be separately heated from inner ring 304 and outer ring 306, while the outer halo 112 is independently coupled to a heater 326. Thus, each of these components may be heated to a same of different temperature as the temperature for each other component of substrate assembly 300.

A halo ring, such as halo ring 302, may be arranged flexibly, so as to define multiple planes, such as a first plane for the inner ring 304 and a second plane for outer ring 306. As such, by providing biasing or heating to a halo ring or inner and outer halo rings, independently of a substrate platen, or independently of an outer halo, the local environment near the periphery of a substrate may be carefully adjusted or controlled to account for edge effects and to improve process uniformity.

In particular embodiments where a silicon halo was employed in an ion beam etch system in conjunction with etching of silicon wafers, etch rate variation across the wafer was improved from 5% non-uniformity when no halo ring was used, to 1% uniformity with the use of a halo ring.

While the above configurations emphasize mounting of a halo ring on the front of an outer halo, other configurations are possible in accordance with embodiments of the disclosure. For example, a ring clamp may instead be used to fasten a halo ring to an outer halo. In addition, rear mounting a halo ring may be used, or electrostatic clamping.

In summation, embodiments described herein provide at least the following technical advantages. For a first advantage, the present embodiments provide flexibility in reducing edge effects by providing detachable halo rings, where the material of the halo ring may be changed to accommodate substrate changes or process changes. For a second advantage, the use of a narrow insert as a halo ring allows materials to be easily replaced to accommodate for wear.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A substrate assembly, comprising:
an outer halo, the outer halo comprising a first material, the outer halo defining a first aperture; and
a halo ring, the halo ring comprising a second material and being disposed at least partially within the first aperture, the halo ring defining a second aperture, concentrically positioned within the first aperture, wherein the halo ring is coupled to accommodate a substrate therein.

2. The substrate assembly of claim 1, wherein the outer halo comprises a metal.

3. The substrate assembly of claim 1, wherein the halo ring comprises silicon or silicon carbide.

4. The substrate assembly of claim 1, wherein the halo ring comprises an outer ring and an inner ring, disposed within the outer ring, the inner ring defining the second aperture, wherein the outer ring comprises a first ring material, and the inner ring comprises a second ring material, different from the first ring material.

5. The substrate assembly of claim 1, further comprising a fastener assembly, the fastener assembly disposed to reversibly attach the outer halo to the halo ring.

6. The substrate assembly of claim 5, wherein the fastener assembly comprises a self-contained spring capsule assembly.

7. The substrate assembly of claim 1, wherein the outer halo comprises outer portion and a ledge, wherein the outer portion comprises a first thickness and the ledge comprises a second thickness, less than the first thickness, wherein an inner edge of the ledge defines the first aperture, and wherein the ledge is disposed to engage the halo ring.

8. The substrate assembly of claim 1, further comprising a backside gap ring, disposed adjacent the halo ring, and within a gap between the halo ring and a substrate position, the substrate position lying within the second aperture.

9. A substrate holder assembly, comprising:
a substrate platen, the substrate platen disposed to support a substrate at a substrate position;
a halo ring, the halo ring being disposed around the substrate position; and
an outer halo, the outer halo comprising a first material, the outer halo being disposed around the halo ring and defining a first aperture, wherein the outer halo is disposed to engage the halo ring,
the halo ring comprising a second material and being disposed at least partially within the first aperture, the halo ring defining a second aperture, concentrically positioned within the first aperture.

10. The substrate holder assembly of claim 9, wherein the outer halo comprises a metal.

11. The substrate holder assembly of claim 9, wherein the halo ring comprises silicon or silicon carbide.

12. The substrate holder assembly of claim 9, wherein the halo ring comprises an outer ring and an inner ring, disposed within the outer ring, the inner ring defining the second aperture, wherein the outer ring comprises a first ring material, and the inner ring comprises a second ring material, different from the first ring material.

13. The substrate holder assembly of claim 9, further comprising a fastener assembly, the fastener assembly disposed to reversibly attach the outer halo to the halo ring.

14. The substrate holder assembly of claim 9, further comprising a backside gap ring, disposed adjacent the halo ring, and within a gap between the halo ring and a substrate position, the substrate position lying within the second aperture.

15. A processing apparatus, comprising:
a process chamber; and
a substrate holder assembly, disposed in the process chamber, the substrate holder assembly comprising:
a substrate platen, the substrate platen disposed to support a substrate at a substrate position;
a halo ring, the halo ring being disposed around the substrate position; and
an outer halo, the outer halo comprising a first material, the outer halo being disposed around the halo ring, and configured to engage the halo ring,
wherein the halo ring comprising a second material, different from the outer halo.

16. The processing apparatus of claim 15, wherein the halo ring comprises silicon or silicon carbide.

17. The processing apparatus of claim 15, wherein the halo ring comprises an outer ring and an inner ring, disposed within the outer ring, the inner ring being disposed around the substrate position.

18. The processing apparatus of claim 17, wherein the outer ring comprises a first ring material, and the inner ring comprises a second ring material, different from the first ring material.

19. The processing apparatus of claim 17, further comprising a first voltage source, electrically coupled to the inner ring, and a second voltage source, electrically coupled to the outer ring, independently of the first voltage source.

20. The processing apparatus of claim 17, further comprising a first heater, coupled to the inner ring, and a second heater, coupled to the outer ring, independently of the first heater.
